(19) United States
(12) Patent Application Publication
(10) Pub. No.: US 2023/0289488 A1
(43) Pub. Date: Sep. 14, 2023

(54) LOGISTICS AREA MANAGEMENT METHOD, LOGISTICS AREA MANAGEMENT SYSTEM, AND NON-TRANSITORY COMPUTER-READABLE STORAGE MEDIUM

(71) Applicant: Toyota Jidosha Kabushiki Kaisha, Toyota-shi (JP)

(72) Inventors: Nobuhisa OTSUKI, Edogawa-ku (JP); Tomoyuki Kaga, Mishima-shi (JP); Hiroya Matsubayashi, Koto-ku (JP); Yuki Ichioka, Kawasaki-shi (JP); Takumi Ban, Setagaya-ku (JP); Hideo Hasegawa, Nagoya-shi (JP)

(73) Assignee: Toyota Jidosha Kabushiki Kaisha, Toyota-shi (JP)

(21) Appl. No.: 18/175,223

(22) Filed: Feb. 27, 2023

(30) Foreign Application Priority Data
Mar. 14, 2022 (JP) 2022-039092

(51) Int. Cl. G06F 30/13

(52) U.S. Cl. CPC G06F 30/13

(57) ABSTRACT

The method of the present disclosure is a management method for a logistics area with a work line constituted of a plurality of work subjects. The method comprises: simulating a work space in which the plurality of work subjects work; monitoring an actual movement of each of the plurality of work subjects in the work space; detecting a deviation between a simulated movement and a monitored actual movement for each of the plurality of work subjects; and acquiring, in response to detection of the deviation, information on a factor affecting a movement of a work subject in which the deviation occurs.

### CROSS-REFERENCE TO RELATED APPLICATION

The present application claims priority under 35 U.S.C. § 119 to Japanese Patent Application No. 2022-039092, filed Mar. 14, 2022, the disclosure of which is incorporated herein by reference in its entirety.

### BACKGROUND

### Field

The present disclosure relates to a technique suitable for use in management of a logistics area with a work line constituted of a plurality of work subjects.

### Background Art

The logistics area has a work line constituted of a plurality of work subjects such as robots and workers. Recently, it has been considered to use simulation for management of such a logistics area. For example, JP2007-188133A discloses a prior art in which a supply chain is optimized by simulation using a simulator reproducing supply chain model. In the prior art, the consistency between the supply chain model reproduced on the simulator and the actual supply chain is verified, and if there is a deviation in the consistency, the cause of the deviation is determined.

However, when considering the application of the prior art described in JP2007-188133A to detection of an abnormality occurring in work subjects working in a logistics area, there is room for improvement in a method of using a simulation result.

In addition to JP2007-188133A, JP2000-077289A and JP2004-196553A can be exemplified as documents showing the technical level of the technical field related to the present disclosure.

### SUMMARY

The present disclosure has been made in view of the above-described problems. An object of the present disclosure is to provide a technique capable of efficiently managing a logistics area with a work line constituted of a plurality of work subjects by using simulation.

The present disclosure provides a logistics area management method and a logistics area management system as a logistics area management technique for achieving the above object.

A logistics area management method according to the present disclosure is a management method for a logistics area with a work line configured of a plurality of work subjects. The logistics area management method of the present disclosure comprises simulating a work space in which the plurality of work subjects work, and monitoring an actual movement of each of the plurality of work subjects in the work space. Furthermore, the logistics area management method of the present disclosure comprises detecting a deviation between a simulated movement and a monitored real movement for each of the plurality of work subjects, and acquiring, in response to detection of the deviation, information on a factor affecting a movement of a work subject in which the deviation occurs.

The logistics area management system of the present disclosure is a management system for a logistics area with a work line constituted of a plurality of work subjects. The logistics area management system of the present disclosure includes a simulator, a monitoring device, and an information acquiring device. The simulator is configured to simulate a work space in which the plurality of work subjects work. The monitoring device is configured to monitor an actual movement of each of the plurality of work subjects in the work space. The information acquiring device is configured to, in response to detection of deviation between a simulated movement and a monitored actual movement in any of the plurality of work subjects, acquire information on a factor affecting a movement of a work subject in which the deviation occurs.

According to the logistics area management technique of the present disclosure, it is possible to acquire information on the factor affecting the movement of the work subject in which a deviation occurs between the simulated movement and the monitored actual movement. Accordingly, it is possible to efficiently detect an abnormality occurring in the work subjects constituting the work line.

In the logistics area management technique of the present disclosure, information on a state of the work subject in which the deviation occurs may be acquired as the information on the factor. According to this, when the abnormality of the work subject is caused by the state of the work subject, the cause of the abnormality can be clarified.

In the logistics area management technique of the present disclosure, when the plurality of work subjects includes a logistics robot, information obtained by an internal sensor of the logistics robot may be acquired as the information on the factor. According to this, when the abnormality of the logistics robot, which is the work subject, can be detected by the internal sensor, the cause of the abnormality can be clarified.

In the logistics area management technique of the present disclosure, information on a work environment of the work subject in which the deviation occurs may be acquired as the information on the factor. According to this, when the abnormality of the work subject is caused by the work environment, the cause of the abnormality can be clarified.

In addition, in the logistics area management technique of the present disclosure, an interlock state between a service provided in the logistics area and a work subject in which the deviation occurs may be acquired as the information on the factor. This makes it possible to determine whether the cause of the deviation is the influence of the service or the abnormality of the work subject.

Further, in the logistics area management technique of the present disclosure, a work speed of each of the plurality of work subjects may be measured, and a difference equal to or greater than a threshold value generated between a simulated work speed and a measured actual work speed may be detected. According to this, it is possible to make the delay of the work of the work subject apparent by the comparison with the simulation, and to detect an abnormality occurring in the work subject based on the delay.

In addition, in the logistics area management technique of the present disclosure, when the plurality of work subjects includes a logistics robot, a braking action of the logistics robot may be detected, and then, a difference equal to or greater than a threshold value in intensity or frequency between a simulated braking action and a detected actual braking action may be detected. According to this, the slowdown and jerky movement of the logistics robot can be made apparent by comparison with the simulation, and an abnormality occurring in the logistics robot can be detected based on such a movement.

Furthermore, in the logistics area management technique of the present disclosure, an operation range of each of the plurality of work subjects may be measured, and a difference equal to or greater than a threshold value between a simulated operation range and a measured actual operation range may be detected. In addition, a flow line of each of the plurality of work subjects may be measured, and a deviation equal to or greater than a threshold value between a simulated flow line and a measured actual flow line may be detected. According to these, it is possible to make a useless movement or an unexpected movement of the work subject apparent by comparison with the simulation and to detect an abnormality occurring in the work subject on the basis of such a movement.

In addition, the present disclosure provides a program for achieving the above object. The program of the present disclosure is a program for causing a computer to manage a logistics area with a work line constituted of a plurality of work subjects. The program of the present disclosure is configured to cause the computer to execute acquiring simulation data obtained by simulating a work space in which the plurality of work subjects work, and acquiring monitored data obtained by monitoring an actual movement of each of the plurality of work subjects in the work space. Further, the program of the present disclosure is configured to cause the computer to execute synchronizing and comparing the simulation data and the monitored data to detect a deviation between a simulated movement and a monitored actual movement for each of the plurality of work subjects, and acquiring, in response to detection of the deviation, information on a factor affecting a movement of a work subject in which the deviation occurs. The program of the present disclosure may be provided by being stored on a non-transitory computer-readable storage medium.

As described above, according to the logistics area management technique of the present disclosure, it is possible to acquire information on the factor affecting the movement of the work subject in which a deviation occurs between the simulated movement and the monitored actual movement. Improvement of the efficiency and reduction of the waste of resources can be achieved by not constantly acquiring information on all work subjects but acquiring information only on the work subject having a deviation from a simulation result.

### BRIEF DESCRIPTION OF THE DRAWINGS

FIG. 1 is a diagram illustrating a configuration of a logistics area management system according to an embodiment of the present disclosure.

FIG. 2 is a diagram showing functions of the information processing device constituting the management system shown in FIG. 1.

FIG. 3 is a diagram showing a first method for detecting an abnormality and specifying the cause thereof.

FIG. 4 is a diagram showing a second method for detecting an abnormality and specifying the cause thereof.

FIG. 5 is a diagram showing a third method of detecting an abnormality and specifying the cause thereof.

FIG. 6 is a diagram showing a fourth method of detecting an abnormality and specifying the cause thereof.

### DETAILED DESCRIPTION

Hereinafter, an embodiment of a logistics area management method, a logistics area management system, and a program of the present disclosure will be described with reference to the drawings. However, in the embodiment described below, when a numerical value such as the number, quantity, amount, range, or the like of each element is mentioned, the idea according to the present disclosure is not limited to the mentioned numerical value except for a case where the numerical value is clearly specified in particular or a case where the numerical value is obviously specified to the numerical value in principle. In addition, a structure or the like described in the following embodiment is not always necessary to the idea according to the present disclosure except for a case where the structure or the like is clearly specified in particular or a case where the structure or the like is obviously specified in principle.

### 1. Configuration of Logistics Area Management System

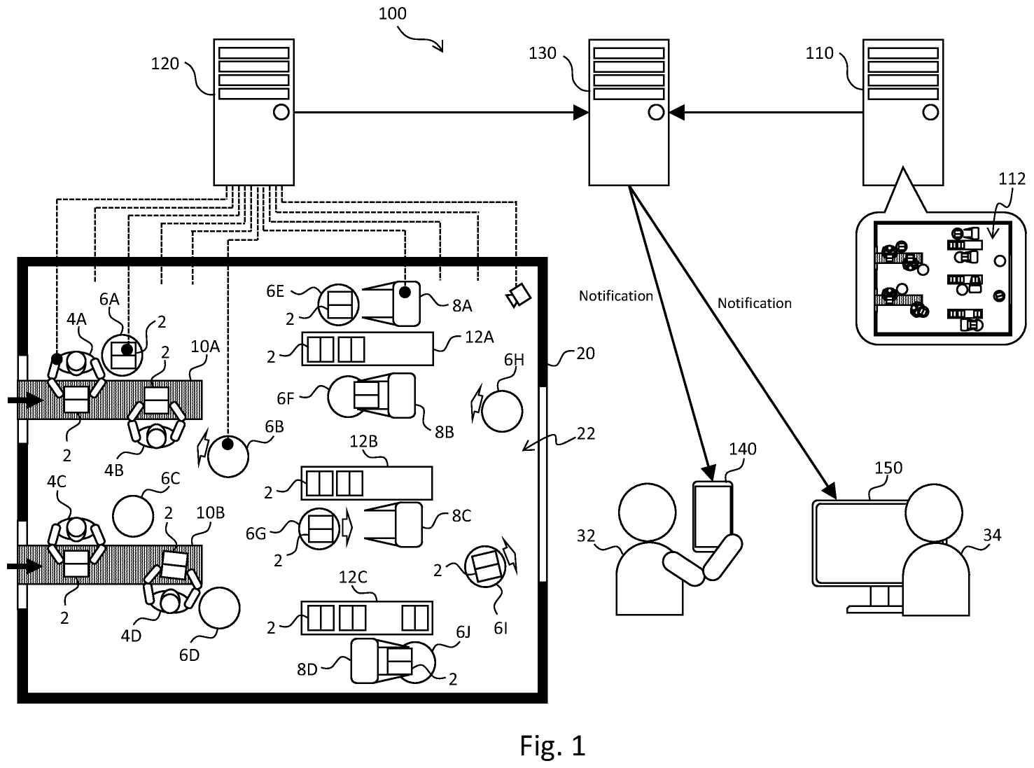

FIG. 1 is a diagram illustrating a configuration of a logistics area management system according to an embodiment of the present disclosure. First, a logistics area to be managed by the management system 100 will be described.

The logistics area managed by the management system 100 is a logistics area with a work line constituted of a plurality of work subjects. Examples of such a logistics area include a relay station (for example, a home delivery office, a collection station in a large-scale apartment house, or the like) for sorting packages, a work place for collecting and sorting waste, a physical distribution zone for receiving parts and shipping products in a manufacturing plant, and the like.

The logistics area 20 illustrated in FIG. 1 is a relay station for sorting loads 2. The logistics area 20 is equipped with conveyors 10A-10B used for sorting incoming loads 2. The logistics area 20 is also equipped with racks 12A-12C for temporary storage of sorted loads 2. The work subjects of the logistics area 20 are workers 4A-4D, transfer robots 6A-6J, and picking robots 8A-8D. These work subjects constitute a work line for sorting and carrying out the loads 2 carried into the logistics area 20.

The conveyors 10A-10B have a mixed flow of loads 2 of various types and destinations. The workers 4A-4D select and pick up the loads 2 from the conveyors 10A-10B. The load 2 to be taken out by each of the workers 4A-4D is determined in advance according to the type and destination of the load 2.

The transfer robots 6A-6G are logistics robots that receive the loads 2 selected and taken out by the workers 4A-4D and transfer the loads 2 to the picking robots 8A-8D. The load 2 to be received by each of the transfer robots 6A-6G is determined in advance according to the type and destination of the load 2. The transferring destination of each of the transfer robots 6A-6G is also determined in advance according to the type and destination of the load 2.

The picking robots 8A-8D are working robots that store the loads 2 received from the transfer robots 6A-6G into the racks 12A-12C. The place where each of the picking robots 8A-8D should store the load 2 is determined in advance according to the type and destination of the load 2. Further, the picking robots 8A-8D select and take out the loads 2 from the racks 12A-12C. The load 2 to be picked up by each picking robot 8A-8D is predetermined by a carry-out schedule.

The transfer robots 6H-6J receive the loads 2 selected and taken out by the picking robots 8A-8D and transfer the loads 2 to the next relay station outside the logistics area 20. The load 2 to be received by each transfer robot 6H-6J is predetermined by the carry-out schedule. The transferring destination of each of the transfer robots 6H-6J is also determined in advance by the carry-out schedule.

The management system 100 includes a digital twin simulator 110, a monitoring device 120, and an information processing device 130. The logistics area management method according to the embodiment of the present disclosure is executed by cooperation of the digital twin simulator 110, the monitoring device 120, and the information processing device 130 that constitute the management system 100.

Each of the digital twin simulator 110, the monitoring device 120, and the information processing device 130 may be an independent computer or may be a virtual computer built in one computer. The management system 100 may be installed on the site of the logistics area 20 or may be installed on a cloud. In addition, when each of the digital twin simulator 110, the monitoring device 120, and the information processing device 130 is an independent computer, a part of the computers may be installed on the site of the logistics area 20 and the remaining computers may be installed on the cloud.

The digital twin simulation device 110 is a computer for realizing a digital twin of the logistics area 20 by simulation. On the virtual space of the digital twin simulator 110, a virtual work space 112 simulating a work space (hereinafter referred to as an actual work space) 22 in which work subjects work in the logistics area 20 is constructed. The digital twin simulator 110 is configured to simulate in real time the movement of each of the work subjects in the virtual work space 112. The digital twin simulator 110 is input with information on actual work conditions of the logistics area 20 such as a load amount, destinations (variation) of loads, the number of workers, and the number of standby robots. In the example illustrated in FIG. 1, all of the workers 4A-4D, the transfer robots 6A-6J, and the picking robots 8A-8D are defined in the virtual work space 112. The digital twin simulator 110 transmits real-time simulation data generated by the simulation to the information processing device 130.

The monitoring device 120 is a computer that monitors the work line of the logistics area 20. The monitoring device 120 is configured to monitor respective actual movements of the workers 4A-4D, the transfer robots 6A-6J, and the picking robots 8A-8D in the actual work space 22 of the logistics area 20. Various means including sensors are used to monitor the movements of the work subjects. For example, optical monitoring means such as a visible light camera and an infrared camera are installed at various locations in the actual work space 22. Moreover, a wireless tag (BLE, RFID, etc.) that is an electromagnetic monitoring means is attached to the load 2. In addition, a millimeter wave radar for detecting a living body is installed in the vicinity of the work space of the workers 4A-4D. Further, a logistics robot such as the transfer robots 6A-6J and the picking robots 8A-8D is provided with a self-position identifying means by which the work subject itself measures and notifies the position thereof. The self-position identification method includes simultaneous localization and mapping (SLAM) by LiDAR, designation from a peripheral feature point by a camera, and a method using an internal sensor such as integration by a wheel encoder and instantaneous moving speed estimation. The monitoring device 120 collects data from the logistics area 20 in real time to generate monitored data, and transmits the monitored data to the information processing device 130. When there is a relationship between a certain work subject and a service provided in the logistics area 20, information on the interlock state between the work subject and the service is acquired from the management center of the service.

The information processing device 130 is a computer that acquires information and generates notification data for the managers 32 and 34 of the logistics area 20 from the acquired information. The information processing device 130 generates the notification data based on the simulation data received from the digital twin simulator 110 and the monitored data received from the monitoring device 120. The notification data is notified to the display terminals 140 and 150. The display terminal 140 is a mobile terminal such as a smartphone, and the display terminal 150 is a desktop PC with a display. The information processing device 130 is connected to the display terminals 140 and 150 via a communication network. The manager 32 carrying the display terminal 140 can perform management work while viewing the display terminal 140 at the site of the logistics area 20. The manager 34 sitting in front of the display terminal 150 can perform management work while looking at the display terminal 150 at a place away from the logistics area 20.

### 2. Function of Information Processing Device

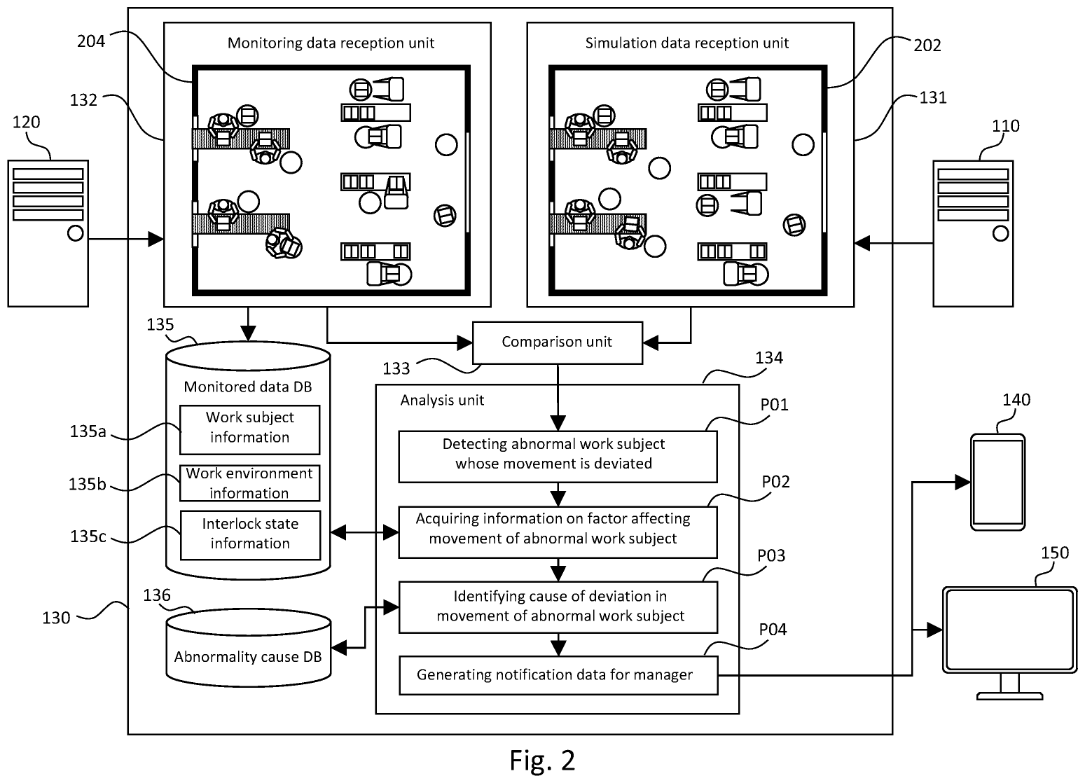

Next, the functions of the information processing device 130 will be described. FIG. 2 is a diagram showing functions of the information processing device 130. The information processing device 130 includes a simulation data reception unit 131, a monitored data reception unit 132, a comparison unit 133, an analysis unit 134, a monitored data database (monitored data DB) 135, and an abnormality cause database (abnormality cause DB) 136. These elements constituting the information processing device 130 are functions of the information processing device 130 realized when a program stored in a memory of the information processing device 130 is executed by a processor of the information processing device 130. The monitored data database 135 and the abnormality cause database 136 may be provided in a memory of the information processing device 130, or may be provided outside the information processing device 130, for example, in a data server on a cloud.

The simulation data reception unit 131 receives simulation data 202 generated by the simulation from the digital twin simulator 110. The monitored data reception unit 132 receives the monitored data 204 obtained from the logistics area 20 in real time from the monitoring device 120.

The comparison unit 133 acquires the simulation data 202 from the simulation data reception unit 131 and acquires the monitored data 204 from the monitored data reception unit 132. The comparison unit 133 synchronizes and compares the simulation data 202 and the monitored data 204. More specifically, the comparison unit 133 compares the movement simulated by the digital twin simulator 110 with the actual movement monitored by the monitoring device 120 for each of the work subjects in the logistics area 20, and calculates the degree of the deviation between them. The comparison result by the comparison unit 133, that is, the information on the degree of the deviation between the simulated movement and the actual movement for each work subject is transmitted from the comparison unit 133 to the analysis unit 134.

The analysis unit 134 analyzes the information acquired from the comparison unit 133 and generates notification data to be notified to the display terminals 140 and 150 based on the analysis result. The analysis unit 134 is configured to execute a first process P01, a second process P02, a third process P03, and a fourth process P04 described below.

The first process P01 is a process of detecting a work subject whose movement is deviated. It is determined for each work subject whether the degree of the deviation between the simulated movement and the actual movement exceeds a threshold value. The threshold value is defined in advance according to the type of the work subject and the content of the movement. A specific example of the movement of the work subject to be compared with the simulation will be described later. When there is a work subject whose degree of the deviation exceeds the threshold value, the work subject is detected as an abnormal work subject.

The second process P02 is a process of acquiring information on a factor affecting the movement of the abnormal work subject (hereinafter, referred to as affecting factor information). The affecting factor information is acquired from the monitored data database 135. The monitored data received by the monitored data reception unit 132 is registered in the monitored data database 135 for at least a certain period of time. The analysis unit 134 extracts information on the abnormal work subject from the information registered in the monitored data database 135.

The information stored in the monitored data reception unit 132 includes work subject information 135a that is information on the state of the work subject. The work subject information 135a includes, for example, information on an operation speed, information on a load state of a motor, information on an operation state of a brake, information on a charging state, information on an operation range, information on positioning accuracy, and the like. When the work subject is a logistics robot such as the transfer robots 6A-6J or a picking robots 8A-8D, the work subject information 135a includes information acquired by an internal sensor of the logistics robot. The work subject information 135a also includes information acquired by an environment sensor such as a camera or a radar installed in the logistics area 20.

The information stored in the monitored data reception unit 132 includes work environment information 135b that is information on the work environment of each work subject. The work environment information 135b includes, for example, information on a positional relationship between the work subject and an object to which the work subject relates, information on an obstacle that interferes with the operation of the work subject, and the like. When a plurality of logistics robots shares a charging device, the work environment information 135b includes a waiting state for the charging device by the plurality of logistics robots. When the plurality of logistics robot moves using an elevator, the work environment information 135b includes a waiting state for the elevator by the plurality of logistics robot. The work environment information 135b includes information acquired by an environment sensor installed in the logistics area 20, information from a back-end server of various facilities, and the like.

The information stored in the monitored data reception unit 132 includes interlock state information 135c that is information on an interlock state between each work subject and a service provided in the logistics area. For example, when the logistics area is an open area, the service provided in the logistics area includes a regular operation bus, an on-demand bus, a home delivery vehicle, and the like passing through the area. In an environment where such a service is provided, an interlock by traffic control is required at an intersection between a flow line of a logistics robot and a flow line of a vehicle. For example, when the use of a vehicle is prioritized over the passage of a logistics robot according to a traffic rule, the logistics robot needs to slow down at the intersection and wait for the vehicle to pass. As the number of vehicles increases, the number of times the logistics robot has to slow down and the waiting time increase accordingly. The number of slowdowns and the waiting time at the intersection are included in the interlock state information 135c, and are acquired from the service management center.

According to the first process P01 and the second process P02 described above, since the affecting factor information is acquired only for the abnormal work subject in which the deviation occurs between the simulated movement and the actual movement, it is possible to achieve efficiency and reduce waste of resources. Note that the following third process P03 and the fourth process P04 may be executed by a computer different from the information processing device 130. That is, the information processing device 130 may be configured as an information acquiring device that performs processes up to the process of acquiring the affecting factor information by the second process P02.

The third process P03 is a process for specifying the cause of the deviation in the movement of the abnormal work subject. The cause is specified based on the work subject information 135a, the work environment information 135b, and the interlock state information 135c related to the abnormal work subject acquired in the second process P02. The abnormality cause database 136 is used to specify the cause. In the abnormality cause database 136, possible abnormality causes are registered in association with the respective contents of the work subject information 135a, the work environment information 135b, and the interlock state information 135c. In the present embodiment, “abnormal” means that the actual movement of the work subject is different from that in the simulation, and “normal” means that the actual movement of the work subject is substantially the same as that in the simulation. That is, the normal/abnormal is a state determined based on the movement by the simulation, and does not necessarily mean a malfunction or a failure of the work subject.

The fourth process P04 is a process for generating notification data to the managers 32 and 34. The abnormal work subject detected in the first process P01 and the cause causing the deviation in the movement of the abnormal work subject specified in the third process P03 are included in the notification data. The information processing device 130 transmits the notification data generated in the fourth process P04 to the display devices 140 and 150.

By the notification from the information processing device 130 to the display terminals 140 and 150, the managers 32 and 34 can know that a situation different from the simulation occurs in the logistics area 20. In addition, the managers 32 and 34 can know what causes the occurrence of the situation different from the simulation from the content of the notification.

In the next section, a method of detecting an abnormality by the first process P01 and specifying a cause by the second process P02 and the third process P03 will be described in detail with specific examples.

### 3. Method for Detecting Abnormality and Specifying Cause Thereof

### 3-1. First Method

In the first method, the work speed of each of all work subjects working in the work space 22 is measured by the monitoring device 120. The comparison unit 133 of the information processing device 130 calculates the difference between the work speed simulated by the digital twin simulator 110 and the actual work speed measured by the monitoring device 120. When a difference between the simulated work speed and the actual work speed for a certain work subject is less than a threshold value, the work subject is determined to be normal. However, if the difference is equal to or greater than the threshold value, the work subject is detected as an abnormal work subject.

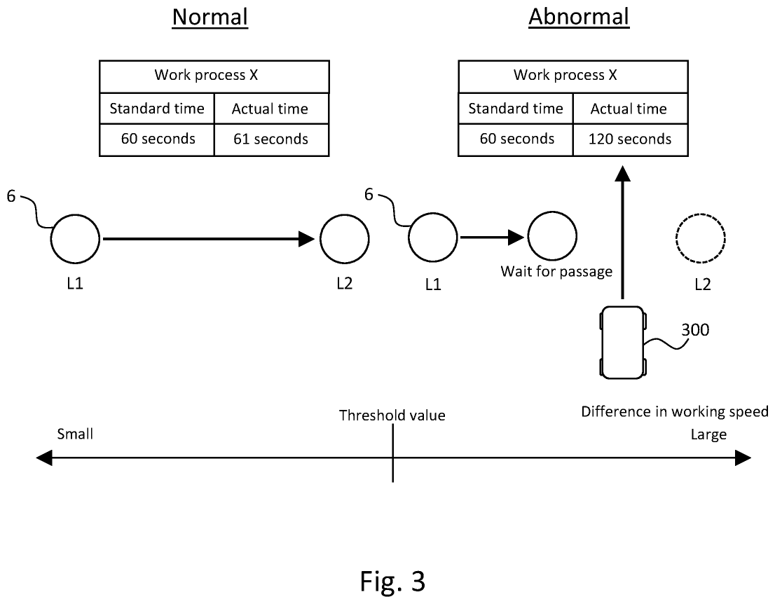

FIG. 3 shows the standard time and actual time of work process X for the transfer robot 6. It is assumed that the work process X is a process in which the transfer robot 6 carries a load from the location L1 to the location L2 and returns to the location L1. The standard time is a time per cycle of the work process X obtained by the simulation by the digital twin simulator 110. The actual time is the time actually required for one cycle of the work process X measured by the monitoring device 120. The difference between the standard time and the actual time represents the difference between the simulated work speed and the actual work speed. FIG. 3 illustrates a normal state in which the difference between the standard time and the actual time is less than the threshold value and an abnormal state in which the difference between the standard time and the actual time is equal to or greater than the threshold value.

When the transfer robot 6 is detected as the abnormal work subject, the affecting factor information on the transfer robot 6 is acquired. In the example shown in FIG. 3, the flow line of the transfer robot 6 and the flow line of the home delivery vehicle 300 intersect each other. The home delivery vehicle 300 is a service provided in the logistics area 20. In accordance with a predefined traffic rule, the transfer robot 6 slows down at the intersection and waits for the home delivery vehicle 300 to pass. The interlock between the home delivery vehicle 300 and the transfer robot 6 is registered in the monitored data database 135 as the interlock state information 135c. Therefore, in the example shown in FIG. 3, the affecting factor information can be acquired from the interlock state information 135c. Based on the acquired affecting factor information, it is specified that the cause of the slowdown of the transfer robot 6 is due to waiting for the passage of the home delivery vehicle 300.

In the example illustrated in FIG. 3, the detected abnormality and the specified result of the cause thereof are notified to the managers 32 and 34, so that the managers 32 and 34 can review the flow line of the transfer robot 6.

### 3-2. Second Method

In a second method, the braking action of each of the logistics robots working in the working space 22 is detected by the monitoring device 120. The comparison unit 133 of the information processing device 130 calculates the difference in intensity or frequency between the braking action simulated by the digital twin simulator 110 and the actual braking action detected by the monitoring device 120. If the difference between the simulated braking intensity or frequency and the actual braking intensity or frequency for a certain logistics robot is less than a threshold value, the logistics robot is determined to be normal. However, if the difference is equal to or greater than the threshold value, the logistics robot is detected as an abnormal work subject.

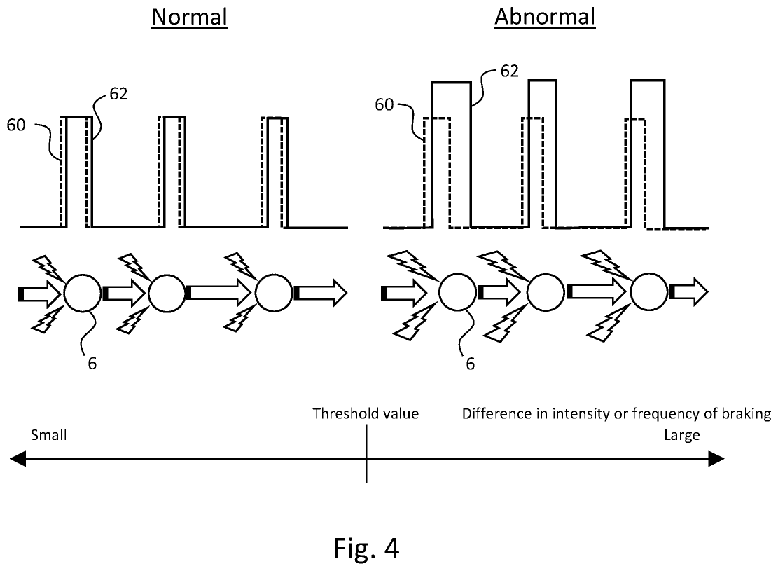

FIG. 4 is a time chart showing an example of a normal state and an example of an abnormal state of a braking action of a certain transfer robot 6. The vertical axis of the time chart indicates the intensity of the braking action. In the example of the normal state, the simulated braking action 60 and the actual braking action 62 substantially coincide with each other. In the example of the abnormal state, the actual braking action 62 has a higher braking intensity and a longer braking time per action than the simulated braking action 60.

When the transfer robot 6 is detected as the abnormal work subject, the affecting factor information on the transfer robot 6 is acquired. In the example shown in FIG. 4, each time the transfer robot 6 applies a brake, the operation state of the brake is acquired by the internal sensor. Information on the operation state of the brake of the transfer robot 6 is registered in the monitored data database 135 as the work subject state information 135a. Therefore, in the example illustrated in FIG. 4, the affecting factor information can be acquired from the work subject state information 135a. Based on the acquired affecting factor information, it is specified that the cause of the slowdown or jerky movement of the transfer robot 6 is the deterioration of the operation state of the brake.

In the example illustrated in FIG. 4, the detected abnormality and the specified result of the cause thereof are notified to the managers 32 and 34, so that the managers 32 and 34 can repair the brake of the transfer robot 6 in which the malfunction occurs.

### 3-3. Third Method

In the third method, the operation range of each of all work subjects working in the work space 22 is measured by the monitoring device 120. The comparison unit 133 of the information processing device 130 calculates a difference between the operation range simulated by the digital twin simulator 110 and the actual operation range measured by the monitoring device 120. If the difference between the simulated operation range for a certain work subject and the actual operation range is less than a threshold value, the work subject is determined to be normal. However, if the difference is equal to or greater than the threshold value, the work subject is detected as an abnormal work subject.

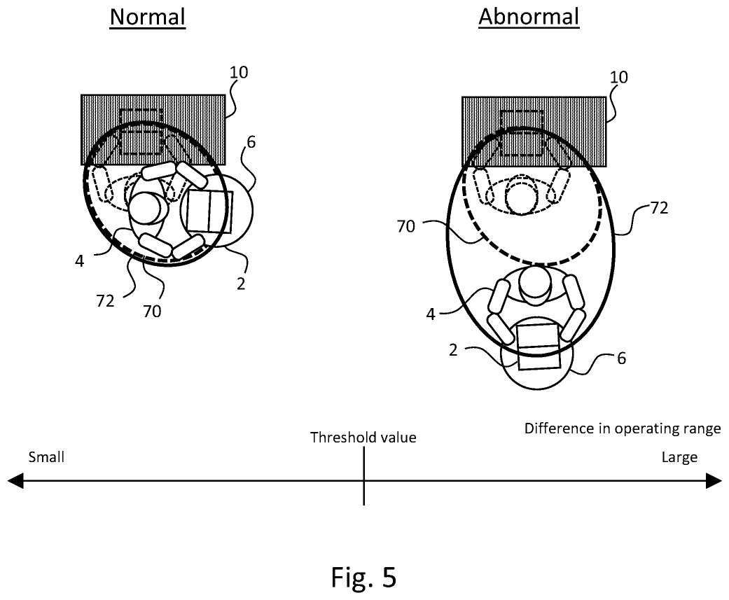

FIG. 5 schematically illustrates an example of a normal state and an example of an abnormal state of an operation range of a certain worker 4. The operation range of the worker 4 is affected by the standby position of the transfer robot 6 that delivers the load 2. In the example of the normal state, the transfer robot 6 stands by at the normal standby position. The normal standby position is a standby position determined from the viewpoint of work efficiency of the worker 4. In the example of the normal state, the operation range 70 of the worker 4 obtained by the simulation and the actual operation range 72 of the worker 4 substantially coincide with each other. On the other hand, in the example of the abnormal state, the transfer robot 6 stands by at a position away from the worker 4 rearward from the normal standby position. In this case, the worker 4 has no choice but to make an unnecessary movement in order to transfer the load 2 to the transfer robot 6. Therefore, in the example of the abnormal state, the actual operation range 72 of the worker 4 is larger than the operation range 70 of the worker 4 obtained by the simulation.

When the worker 4 is detected as the abnormal work subject, the affecting factor information on the worker 4 is acquired. In the example illustrated in FIG. 5, the standby position of the transfer robot 6 to which the worker 4 is delivering the load 2 is acquired by an environment sensor such as a camera. The information on the standby position of the transfer robot 6 is registered in the monitored data database 135 as the work environment information 135b. Therefore, in the example shown in FIG. 5, the affecting factor information can be acquired from the work environment information 135b. Based on the acquired affecting factor information, it can be specified that the cause of the expansion of the operation range of the worker 4 is the shift of the standby position of the transfer robot 6.

In the example illustrated in FIG. 5, the managers 32 and 34 is notified of the detected abnormality and the specified result of the cause thereof, so that the managers 32 and 34 can inspect the transfer robot 6 in which the shift occurs in the standby position.

### 3-4. Fourth Method

In the fourth method, the respective flow lines of all work subjects working in the work space 22 are measured by the monitoring device 120. The comparison unit 133 of the information processing device 130 calculates the degree of the deviation between the flow line simulated by the digital twin simulator 110 and the actual flow line measured by the monitoring device 120. When a degree of deviation between the simulated flow line and the actual flow line for a certain work subject is less than a threshold value, the work subject is determined to be normal. However, if the difference is equal to or greater than the threshold value, the work subject is detected as an abnormal work subject.

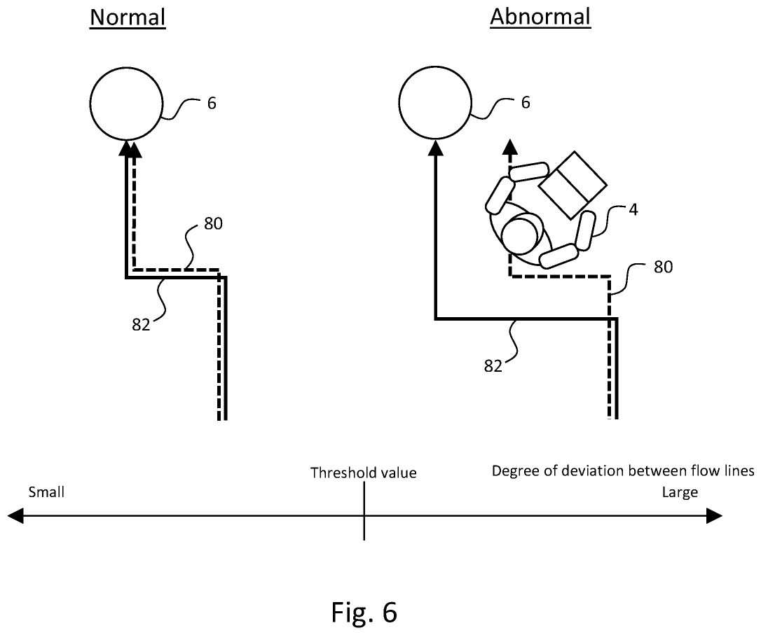

FIG. 6 schematically illustrates an example of a normal state and an example of an abnormal state of a flow line of a certain transfer robot 6. In the example of the normal state, the flow line 80 of the transfer robot 6 obtained by the simulation and the flow line 82 of the actual transfer robot 6 substantially coincide with each other. On the other hand, in the example of the abnormal state, the flow line 80 obtained by the simulation and the worker 4 interfere with each other. In this case, the transfer robot 6 has to travel so as to avoid the worker 4. Therefore, in the example of the abnormal state, a deviation occurs between the flow line 80 of the transfer robot 6 obtained by the simulation and the actual flow line 82 of the transfer robot 6.

When the transfer robot 6 is detected as the abnormal work subject, the affecting factor information on the transfer robot 6 is acquired. In the example illustrated in FIG. 6, the presence of the worker 4 interfering with the flow line of the transfer robot 6 is acquired by an environment sensor such as a camera. The information on the worker 4 interfering with the flow line is registered in the monitored data database 135 as the work environment information 135b. Therefore, in the example shown in FIG. 6, the affecting factor information can be acquired from the work environment information 135b. Based on the acquired affecting factor information, it is specified that the cause of the deviation of the flow line of the transfer robot 6 is the worker 4 interfering with the flow line.

In the example illustrated in FIG. 6, the detected abnormality and the specified result of the cause thereof are notified to the managers 32 and 34, so that the managers 32 and 34 can consider a change in the flow line of the transfer robot 6 or a change in the work area of the worker 4.

What is claimed is:

1. A management method for a logistics area with a work line constituted of a plurality of work subjects, the management method comprising:
simulating a work space in which the plurality of work subjects work;
monitoring an actual movement of each of the plurality of work subjects in the work space;
detecting a deviation between a simulated movement and a monitored actual movement for each of the plurality of work subjects; and
acquiring, in response to detection of the deviation, information on a factor affecting a movement of a work subject in which the deviation occurs.

2. The management method according to claim 1, wherein
the acquiring the information on the factor comprises acquiring information on a state of the work subject in which the deviation occurs as the information on the factor.

3. The management method according to claim 1, wherein
the plurality of work subjects includes a logistics robot, and
the acquiring the information on the factor comprises acquiring information obtained by an internal sensor of the logistics robot as the information on the factor.

4. The management method according to claim 1, wherein
the acquiring the information on the factor comprises acquiring information on a work environment of a work subject in which the deviation occurs as the information on the factor.

5. The management method according to claim 1, wherein
the acquiring the information on the factor comprises acquiring an interlock state between a service provided in the logistics area and a work subject in which the deviation occurs as the information on the factor.

6. The management method according to claim 1, wherein
the monitoring the actual movement of each of the plurality of work subjects comprises measuring a work speed of each of the plurality of work subjects, and
the detecting the deviation comprises detecting a difference equal to or greater than a threshold value generated between a simulated work speed and a measured actual work speed.

7. The management method according to claim 1, wherein
the plurality of work subjects includes a logistics robot,
the monitoring the actual movement of each of the plurality of work subjects comprises detecting a braking action of the logistics robot, and
the detecting the deviation comprises detecting a difference equal to or greater than a threshold value in intensity or frequency between a simulated braking action and a detected actual braking action.

8. The management method according to claim 1, wherein
the monitoring the actual movement of each of the plurality of work subjects comprises measuring an operating range of each of the plurality of work subjects, and
the detecting the deviation comprises detecting a difference equal to or greater than a threshold value between a simulated operating range and a measured actual operating range.

9. The management method according to claim 1, wherein
the monitoring the actual movement of each of the plurality of work subjects comprises measuring a flow line of each of the plurality of work subjects, and
the detecting the deviation comprises detecting a deviation equal to or greater than a threshold value between a simulated flow line and a measured actual flow line.

10. A management system for a logistics area with a work line constituted of a plurality of work subjects, comprising:
a simulator configured to simulate a work space in which the plurality of work subjects work;
a monitoring device configured to monitor an actual movement of each of the plurality of work subjects in the work space; and
an information acquiring device configured to, in response to detection of a deviation between a simulated movement and a monitored actual movement in any of the plurality of work subjects, acquire information on a factor affecting a movement of a work subject in which the deviation occurs.

11. A non-transitory computer-readable storage medium storing a program for causing a computer to execute processing for managing a logistics area with a work line constituted of a plurality of work subjects, the processing comprising:
acquiring simulation data obtained by simulating a work space in which the plurality of work subjects work;
acquiring monitoring data obtained by monitoring an actual movement of each of the plurality of work subjects in the work space;
synchronizing and comparing the simulation data and the monitored data to detect a deviation between a simulated movement and a monitored actual movement for each of the plurality of work subjects; and
acquiring, in response to detection of the deviation, information on a factor affecting a movement of a work subject in which the deviation occurs.
